(19) United States
(12) Patent Application Publication
(10) Pub. No.: US 2026/0037016 A1
(43) Pub. Date: Feb. 5, 2026

(54) MULTI-AXIS ROTARY HANDLE

(71) Applicant: HANWIT PRECISION INDUSTRIES LTD., New Taipei (TW)

(72) Inventors: Ying-Chih TSENG, New Taipei (TW); Ming-De WU, New Taipei (TW)

(21) Appl. No.: 18/789,093

(22) Filed: Jul. 30, 2024

(51) Int. Cl. G05G 1/04; H05K 5/02

(52) U.S. Cl. CPC G05G 1/04; H05K 5/023

(57) ABSTRACT

A multi-axis rotary handle includes a base providing a shaft hole and a guide surface, a shaft device having a rotating rod inserted into the shaft hole of the base, a rotating shaft assembled on the rotating rod can be horizontally rotated and a protruding rod provided on one end of the rotating shaft, and a handle having a coupling groove located on one side thereof and movably assembled at the rotating rod to achieve axial rotation displacement at the rotating rod and longitudinal rotation along the protruding rod on one side of the rotating shaft and swinging up and down in the vertical direction, so as to achieve the purpose of providing the handle with multi-axis rotation drive, which is convenient for active rotation and not easy to block the operating space.

### BACKGROUND OF THE INVENTION

### Field of the Invention

The present invention provides a multi-axis rotary handle, in particular a rotary handle capable of horizontal axial rotation and vertical longitudinal flipping and swinging, wherein the rotating rod of the shaft device is assembled at the shaft hole of the base, and the rotating shaft is assembled on the rotating rod, so that the coupling groove on one side of the handle is assembled on the rotating rod, and the rotating shaft hole of the handle is assembled on the protruding rod on one side of the rotating shaft to achieve the purpose of providing the handle with axial rotation at the rotating rod and longitudinal flipping and swinging at the protruding rod.

### Description of the Related Art

With the continuous progress and development of electronic technology, computer technology has brought people convenience, comfort, speed and other high-efficiency functions in life and work. Therefore, the application functions of electronic technology, computer systems, etc. are becoming increasingly powerful and the scope is becoming increasingly wider. In addition to general personal computers, there are also centrally managed systems such as industrial computer rooms, building central control systems, central control systems for automated factory operation systems, and central processing control systems for audio and video playback. It can simultaneously connect multiple computer hosts, servers, operating conversion systems, etc., and assemble them in a stacked manner inside a large electronic equipment chassis to form upper and lower stacked boxes. The boxes can be pulled out or pushed from the side of the electronic equipment chassis to assemble or repair various computer operating systems. Because multiple operating host systems are combined, when various computer operating systems need to be tested, updated, or other related operations, the boxes on different layers must be pulled out of the electronic equipment chassis one by one to facilitate testing or related maintenance operations. Therefore, the various multi-layered boxes assembled in the electronic equipment chassis are all provided with a simple buckling structure, so that each box can be easily assembled inside the chassis or pulled out from the chassis by the buckling mechanism.

The stacked boxes assembled inside the electronic equipment chassis are equipped with various electronic and circuit systems. In addition to general word processing and application execution, they can also connect to the Internet to search for a lot of information. As a result, computers occupy a very important position in daily life and work. In addition to the related peripheral equipment, each box also has a removable slot space for conveniently plugging in a mobile hard drive, or for electrically plugging in electronic devices such as a CD player or a multimedia player, in order to facilitate the expansion of data storage and the preservation and confidentiality of data. This means that applications can be expanded effectively without occupying the host space of each box. However, the slot space set up in each box host is a slot frame space composed of a fixed frame. When using the slot space to plug in electronic products, the assembly path or space is often blocked or restricted by the handle provided on the outside of the box. This causes inconvenience in plugging and unplugging the electronic products and the host inside the box, which needs to be improved.

Therefore, how to solve the inconvenience and trouble of pulling out and pushing each box in the stacked electronic equipment chassis, and the problem and loss that the handle on each box for pulling out easily obstruct the assembly path and space for the electronic circuit inside the box and external electronic products is the direction that the relevant manufacturers in this industry are eager to research and improve.

### SUMMARY OF THE INVENTION

Therefore, in view of the above-mentioned problems and deficiencies, the inventor collected relevant information, and after many evaluations and considerations, he designed the invention of this multi-axis rotary handle.

The main object of the present invention is that the multi-axis rotary handle is provided with a penetrating shaft hole in the base, and the side of the shaft hole has a guide surface, so that the rotating rod of the shaft device can be movably inserted into the shaft hole of the base; a rotating shaft that can rotate horizontally is assembled at the rotating rod, and a protruding rod is provided on one side of the rotating shaft to allow the coupling groove on one side of the handle to be movably assembled on the rotating rod of the shaft device, a rotating shaft hole is provided on one side of the coupling groove to be assembled at the protruding rod on one side of the rotating shaft, the handle can be axially rotated by using the coupling groove on one side of the rotating rod and can be longitudinally rotated along the protruding rod on one side of the rotating shaft and swung up and down in the vertical direction, so as to achieve the purpose of providing the handle with multi-axis rotation drive, and the double-axis structure design of the shaft device can be used to provide a damping structure for the handle, which is convenient for rotation without blocking the operating space.

Another object of the present invention is that the base includes a first base block and a second base block, and a penetrating shaft hole provided on the first base block and the second base block, a receiving groove provided between the first base block and the second base block, a guide surface provided on one side of the shaft hole of the second base block and extending downward and outward, a seat plate extending outward from one side of the first base block and the second base block and a shaft groove provided on the side of the seat plate adjacent to the second base block and extending outward from the shaft hole; the rotating rod of the shaft device is passed through the shaft holes at the first base block and the second base block so that the rotating shaft assembled on the rotating rod is located at the receiving groove; the seat plate is available for assembly at a preset mechanism, which may be a hard drive, a multimedia player, a server, an optical drive, a telecommunications case, a sliding drawer, or a computer motherboard, etc., the rotating shaft of the shaft device is located at the rotating rod and rotates horizontally along the receiving groove in an axial direction, and a spherical arc guide surface is provided on the other side of the rotating shaft relative to the protruding rod.

Still another object of the present invention is that the handle comprises a U-shaped coupling groove located on one side thereof, a stop arm extending outward on one side of the coupling groove, an inclined guide surface located on the side of the stop arm and extending obliquely to the coupling groove, a swing arm provided on the longitudinal side of the coupling groove relative to the stop arm, a rotating shaft hole located on the swing arm that can be assembled on the protruding rod on one side of the rotating shaft, and a limit member, which can be a screw, a rivet or a pin, provided on one side of the rotating shaft hole of the swing arm and assembled at the protruding rod (it can be locked, riveted, tightly fitted, interference fit, adhesively bonded or welded, etc.) to hold against the wall of the rotating shaft hole, thereby preventing the swing arm and the protruding rod from separating or falling off.

Still another object of the present invention is that the handle is equipped with a buckling device on the other side of the coupling groove and the rotating shaft hole, the buckling device comprises a receiving space located on the side of the handle, a fixing hole disposed on the handle on the side of the receiving space, a cover assembled at the fixing hole and covering the receiving space, a buckle assembled on the cover and an elastic member located in the receiving space and supported on one side of the actuating side, the buckle has an actuating side provided on one side thereof and a buckle side provided on an opposite side thereof and protruding out of the receiving space and the cover, the elastic member is selectively an elastic leaf spring, a spring or a coil spring.

Still another object of the present invention is that the buckling device on the other side of the handle is equipped with a positioning buckle rod for buckling and unbuckle on the buckle side, the positioning buckle rod is equipped with a mounting seat that is assembled on the preset mechanism, and the preset mechanism can be a hard drive, a multimedia player, a server, an optical disc drive, a sliding drawer, or a computer motherboard.

### BRIEF DESCRIPTION OF THE DRAWINGS

FIG. 1 is a three-dimensional external view of the present invention..

FIG. 2 is a three-dimensional exploded view of the present invention.

FIG. 3 is a three-dimensional exploded view of the present invention from another viewing angle.

FIG. 4 is a three-dimensional external view of an implementation example of the present invention.

FIG. 5 is a three-dimensional external view of a preferred implementation embodiment of the present invention.

FIG. 6 is an enlarged partial top view of the preferred implementation embodiment of the present invention.

FIG. 7 is an enlarged partial front view of the preferred implementation embodiment of the present invention.

FIG. 8 is an enlarged partial top view of the preferred implementation embodiment of the present invention when the handle is in motion.

FIG. 9 is an enlarged partial top view of the preferred implementation embodiment of the present invention, showing the handle being pulled out during operation.

FIG. 10 is an enlarged partial top view of the preferred implementation embodiment of the present invention after the handle is actuated.

FIG. 11 is an enlarged partial top view of the preferred implementation embodiment of the present invention, showing the handle rotating after being actuated.

FIG. 12 is an enlarged partial front view of the preferred implementation embodiment of the present invention, showing the handle rotating after being actuated.

FIG. 13 is an enlarged partial top view of the buckling device of the handle of another embodiment of the present invention.

FIG. 14 is an enlarged partial top view of the buckling device of the handle of another embodiment of the present invention when the buckling device is in motion.

### DETAILED DESCRIPTION OF THE INVENTION

In order to achieve the above objects and effects, the technical means and structures adopted by the present invention are described in detail below with respect to the preferred embodiment of the present invention, so as to facilitate a complete understanding.

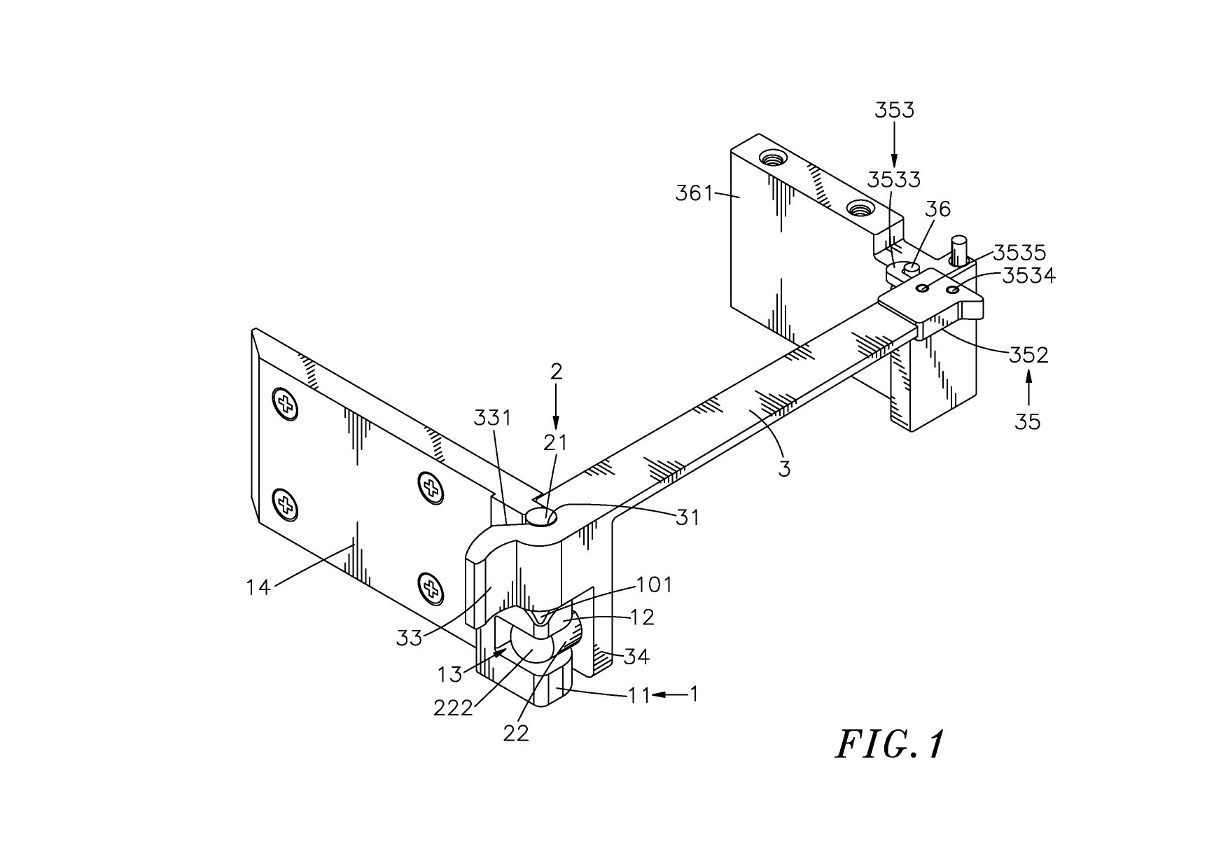

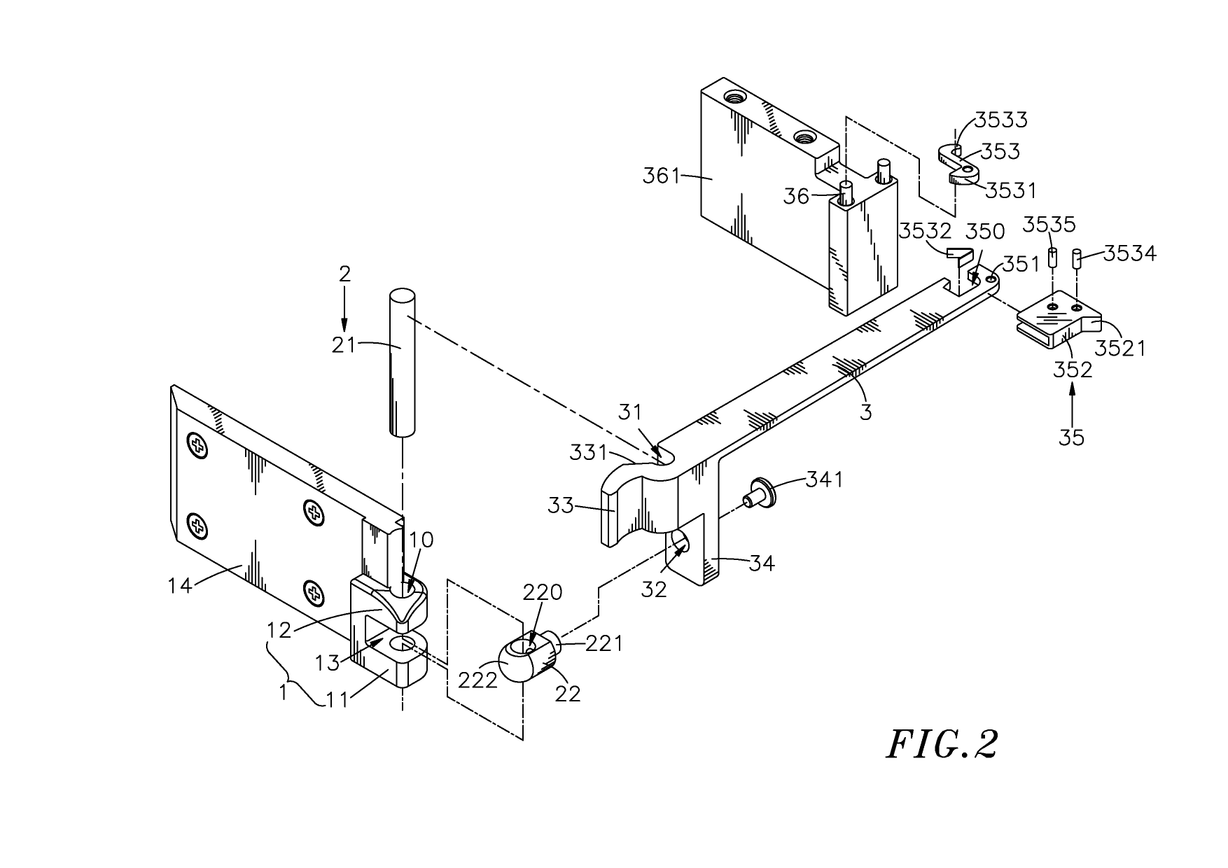

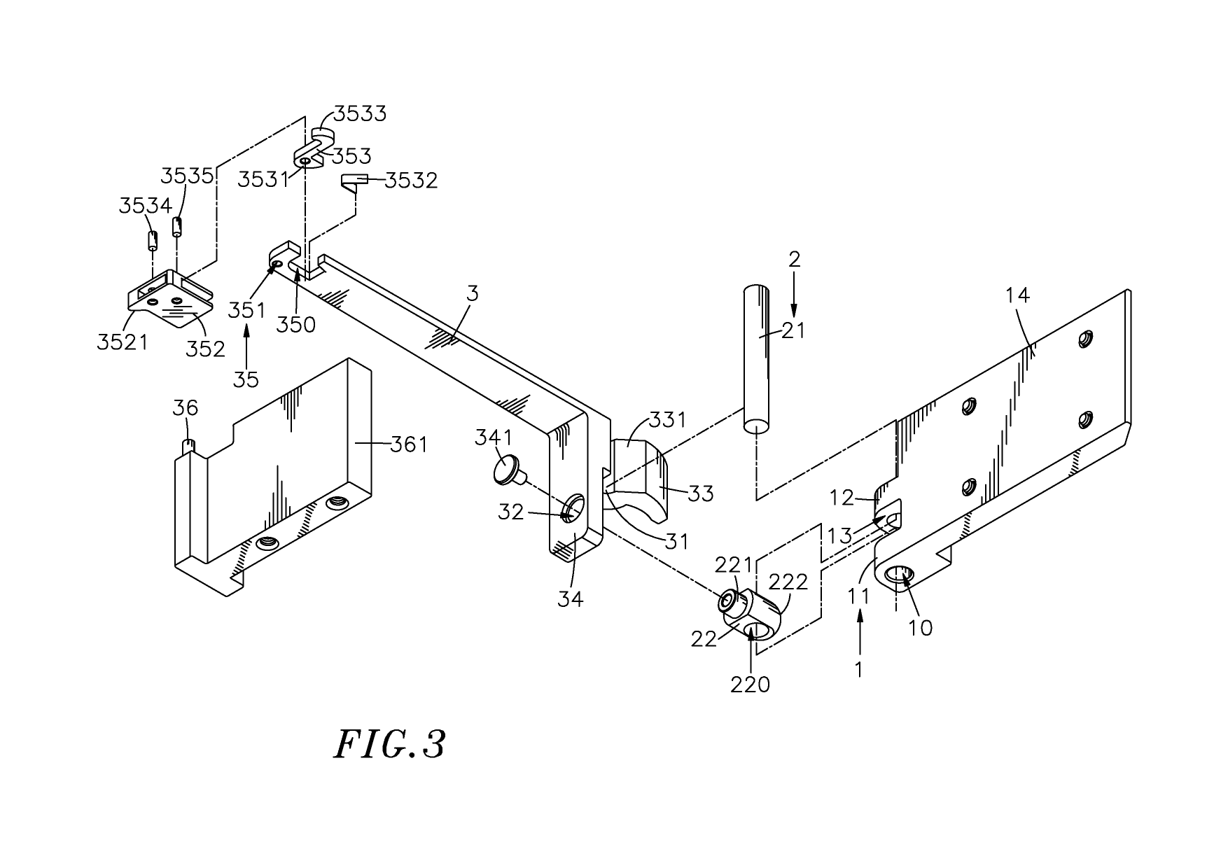

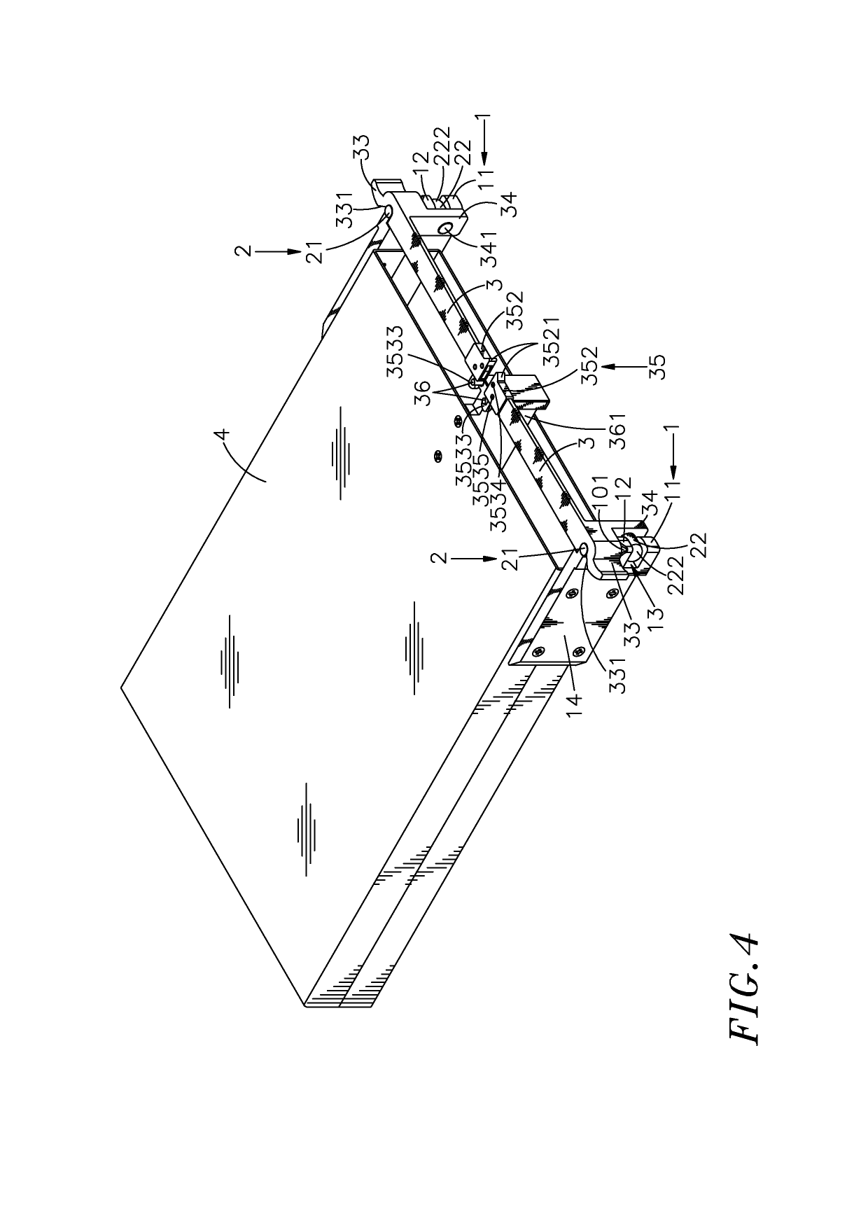

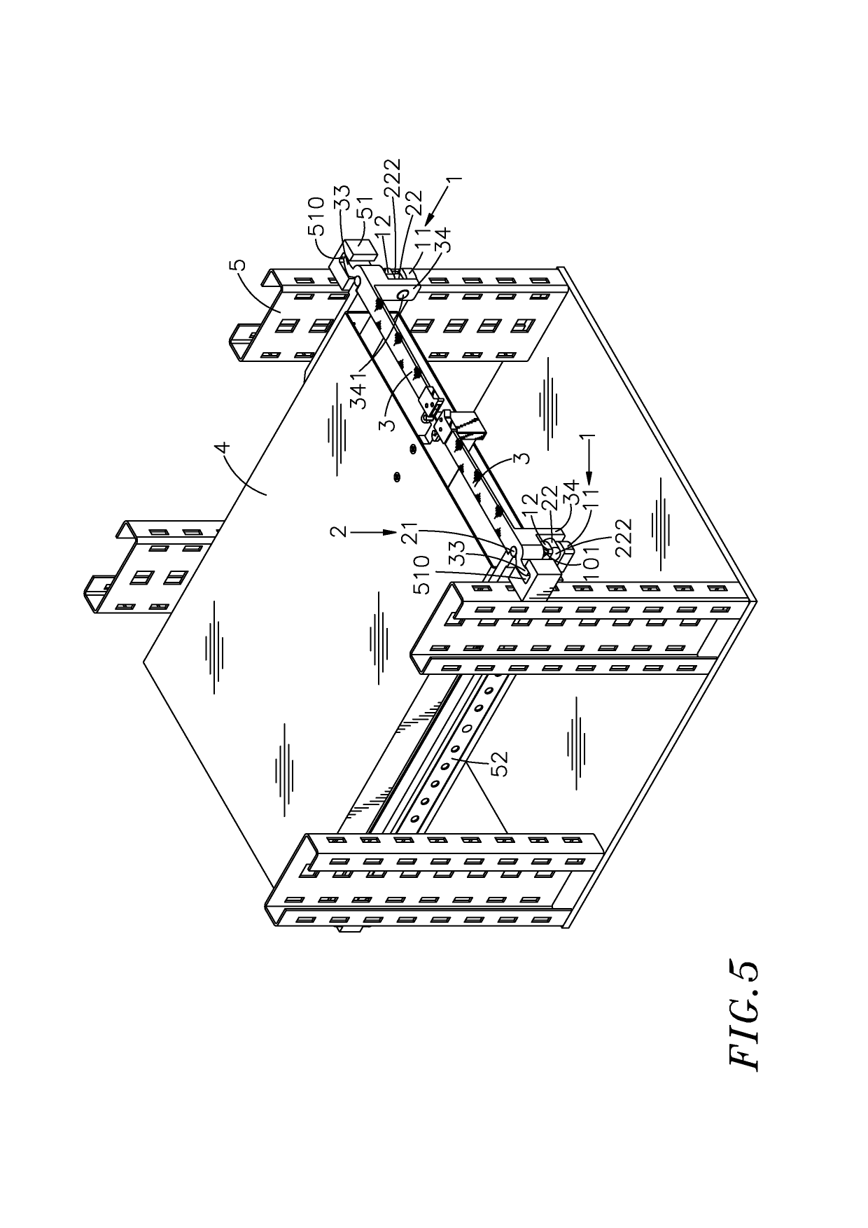

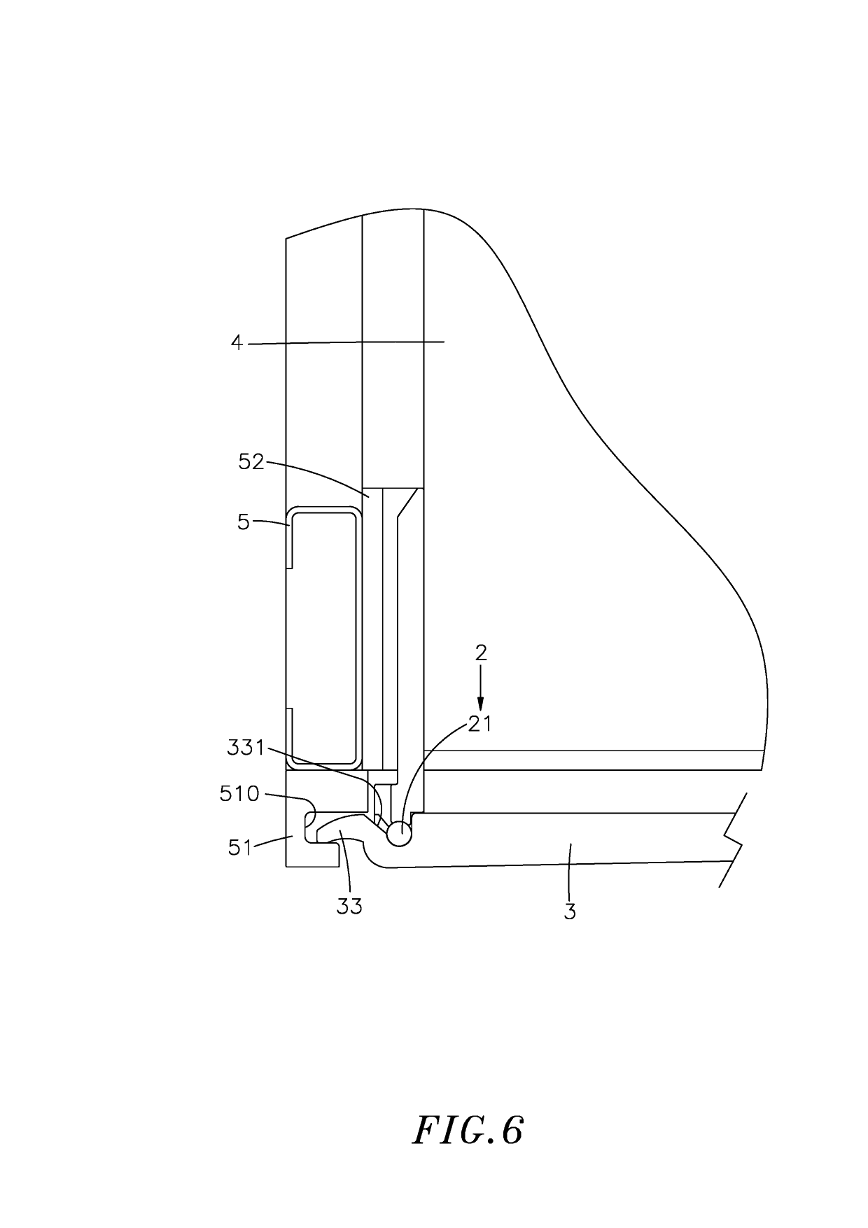

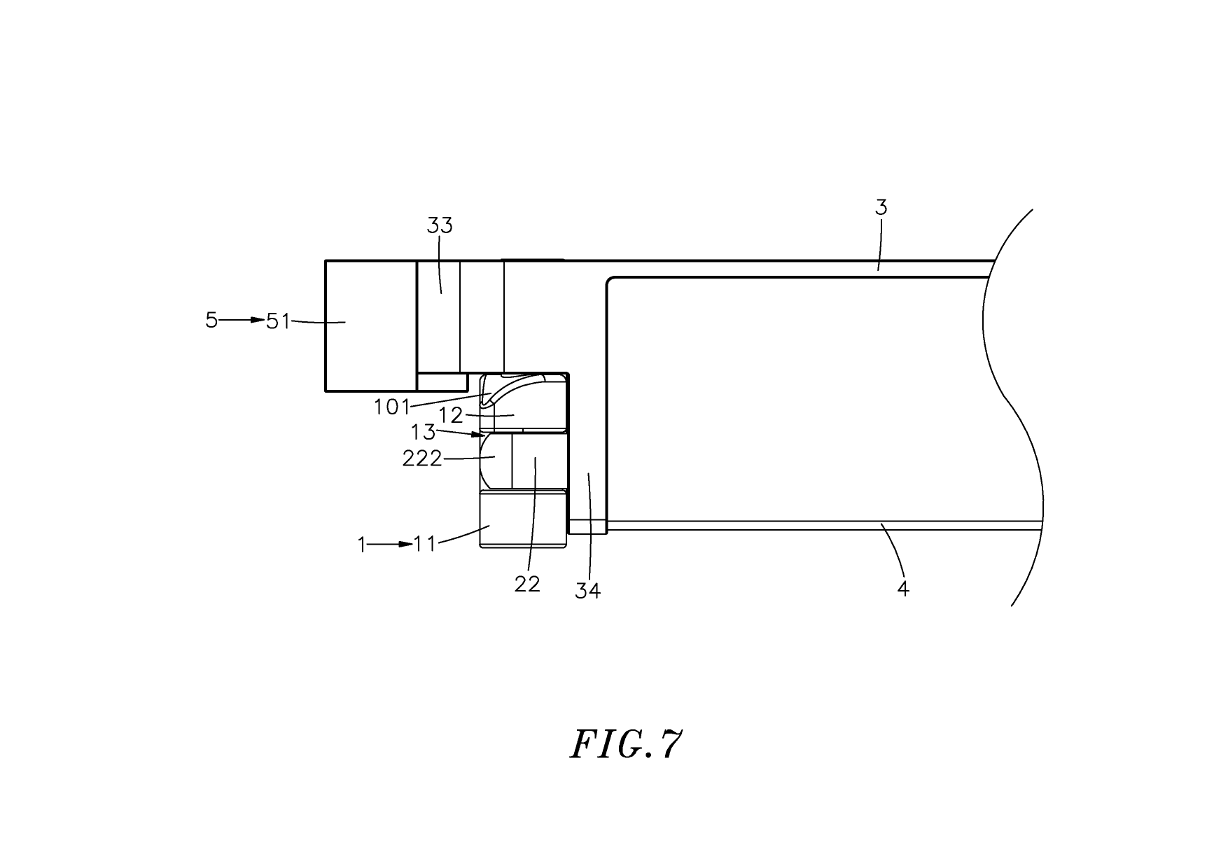

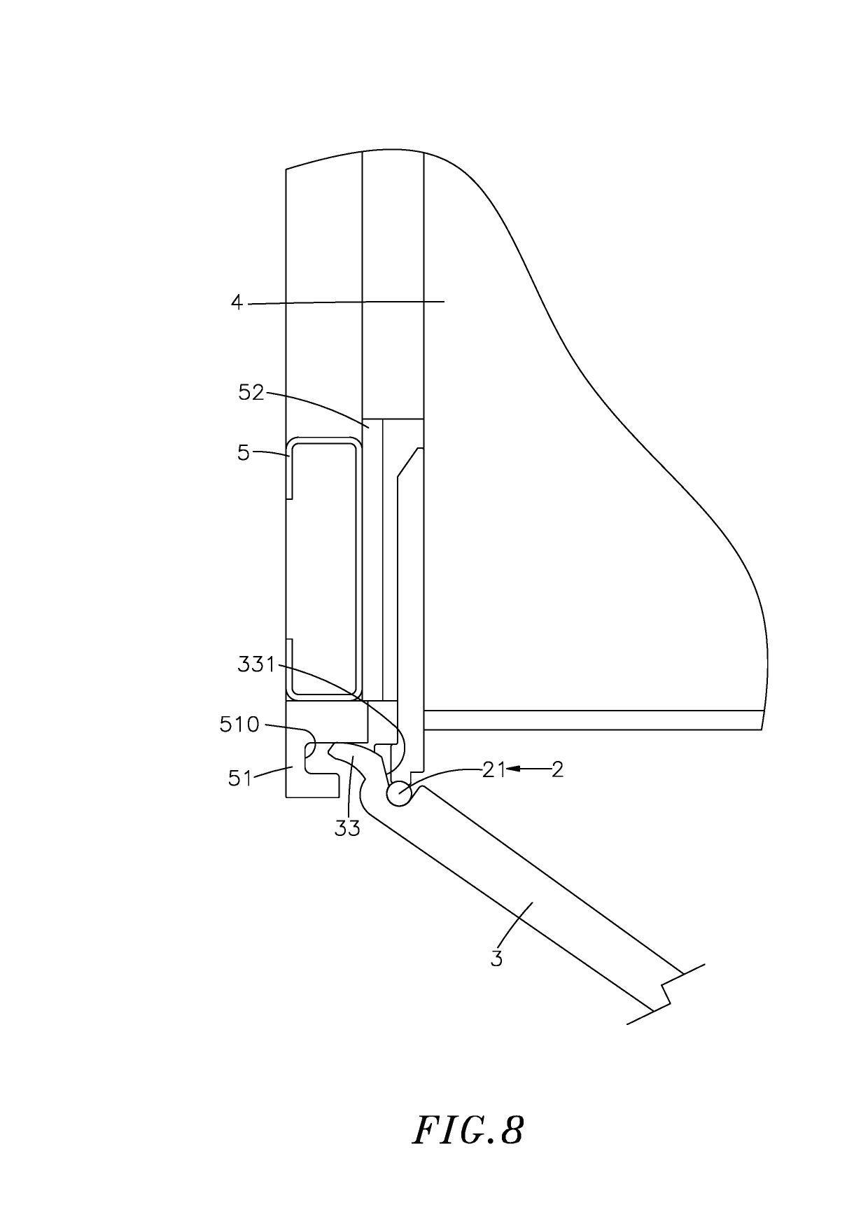

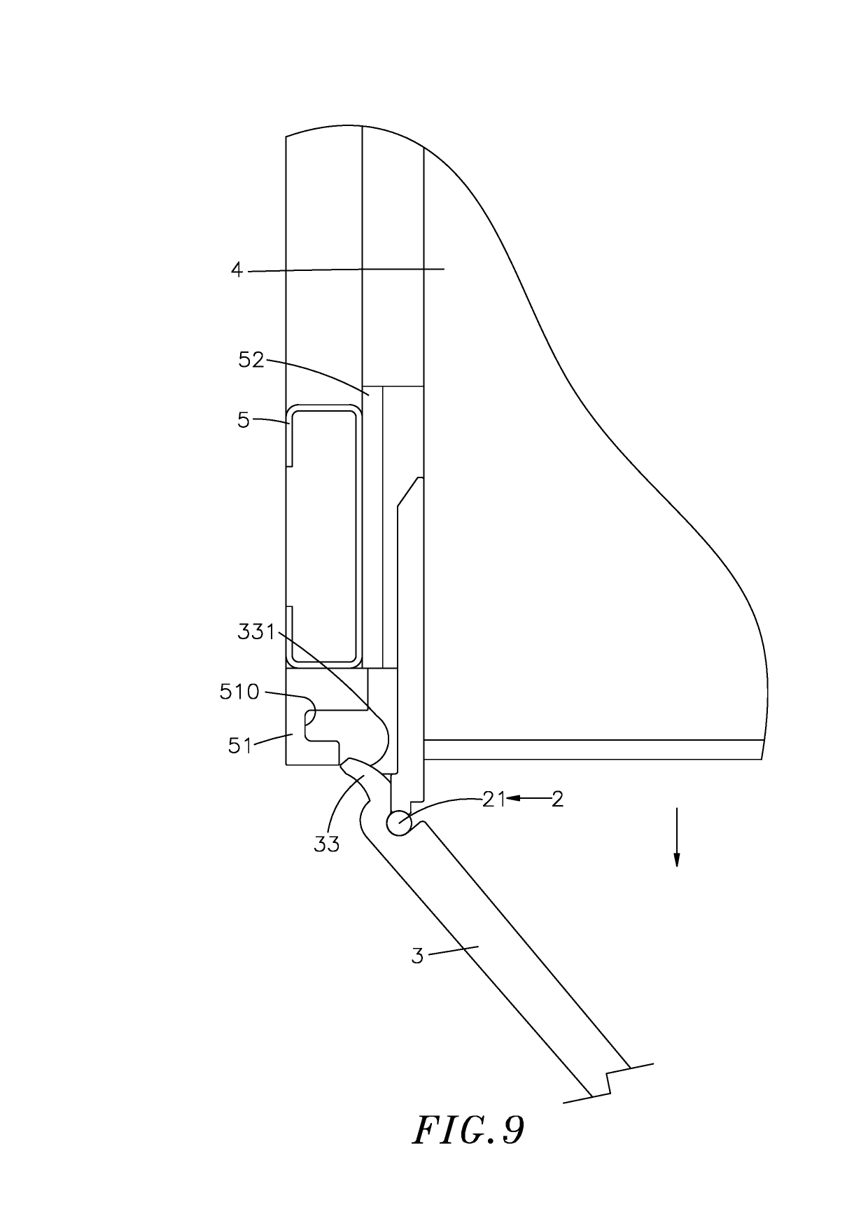

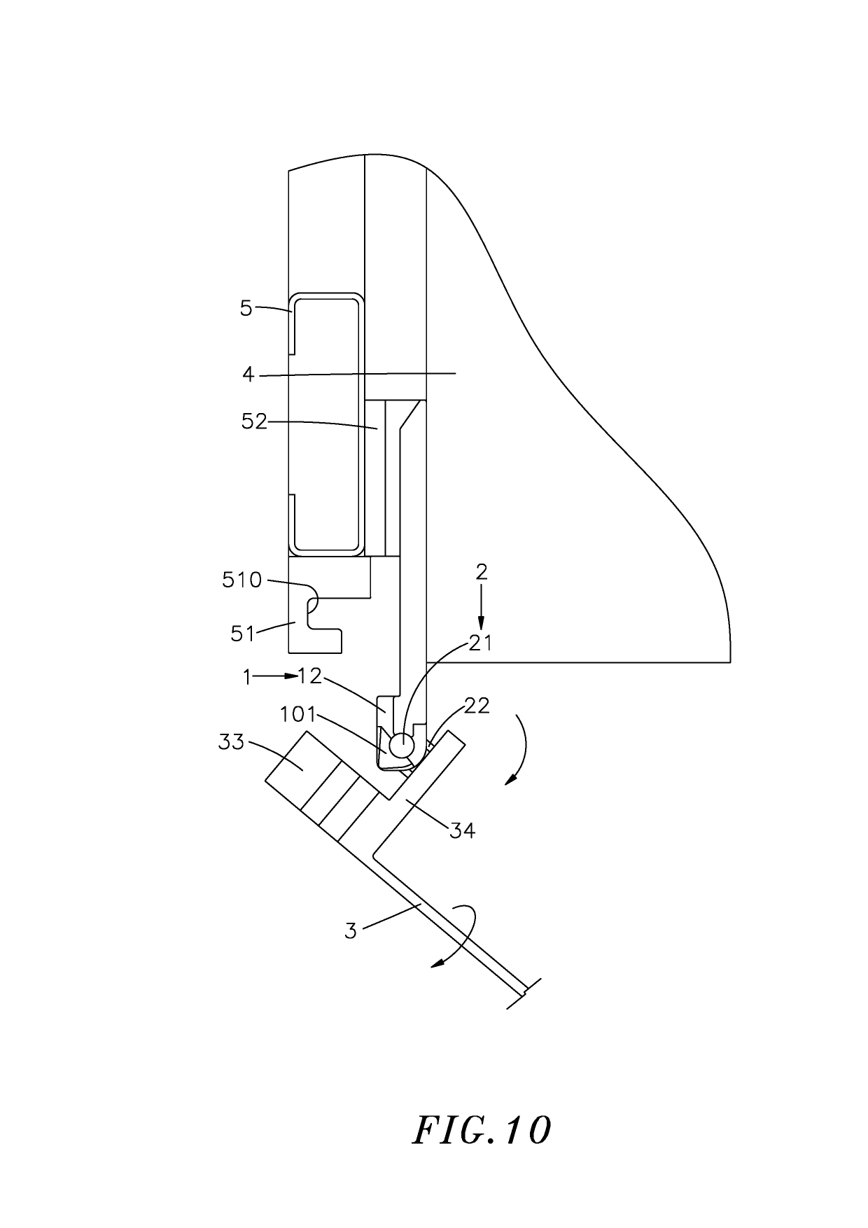

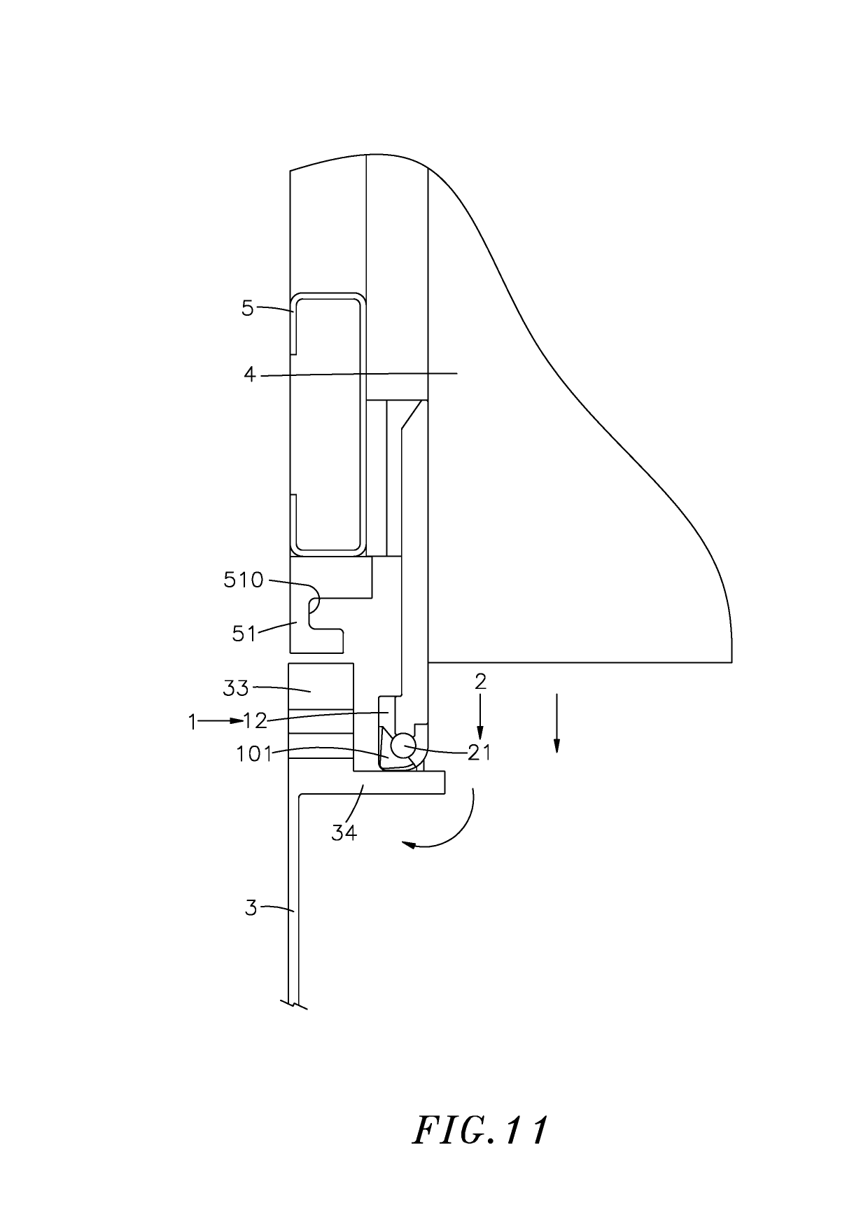

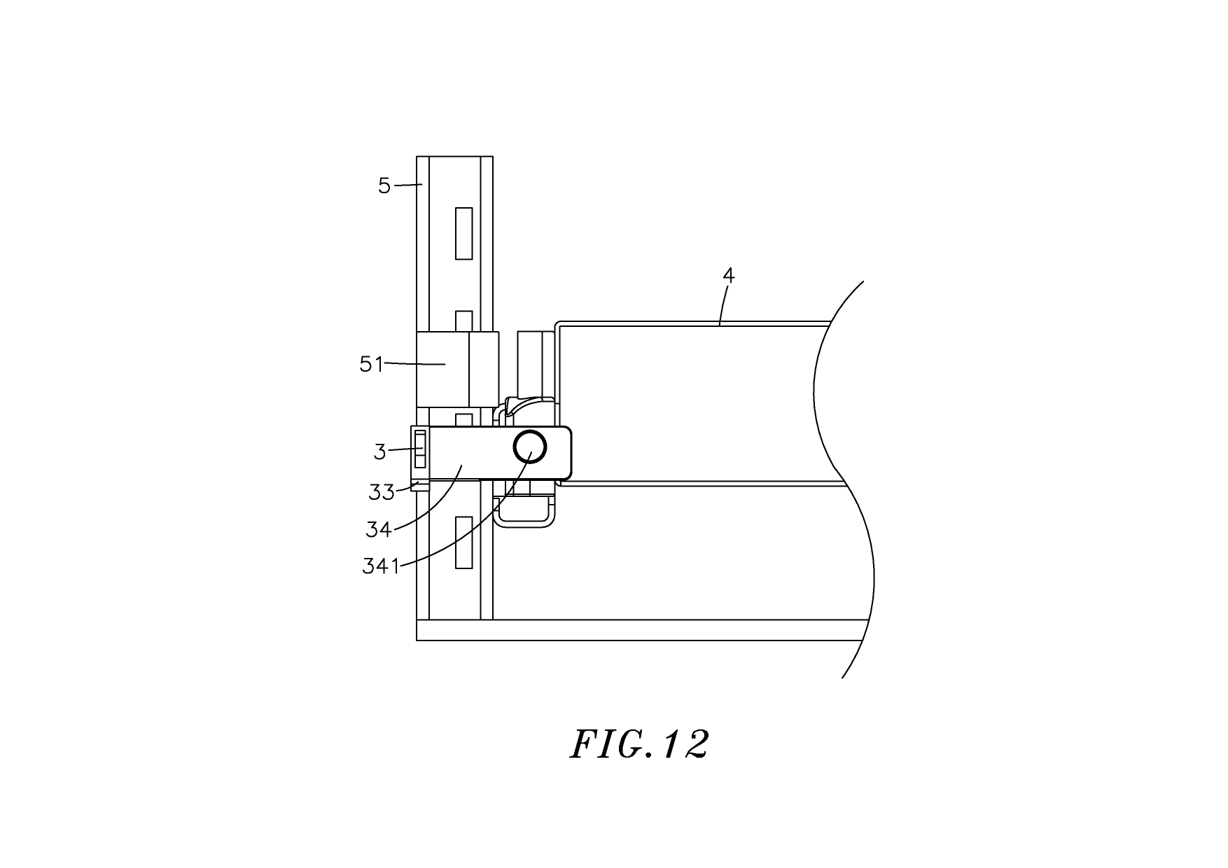

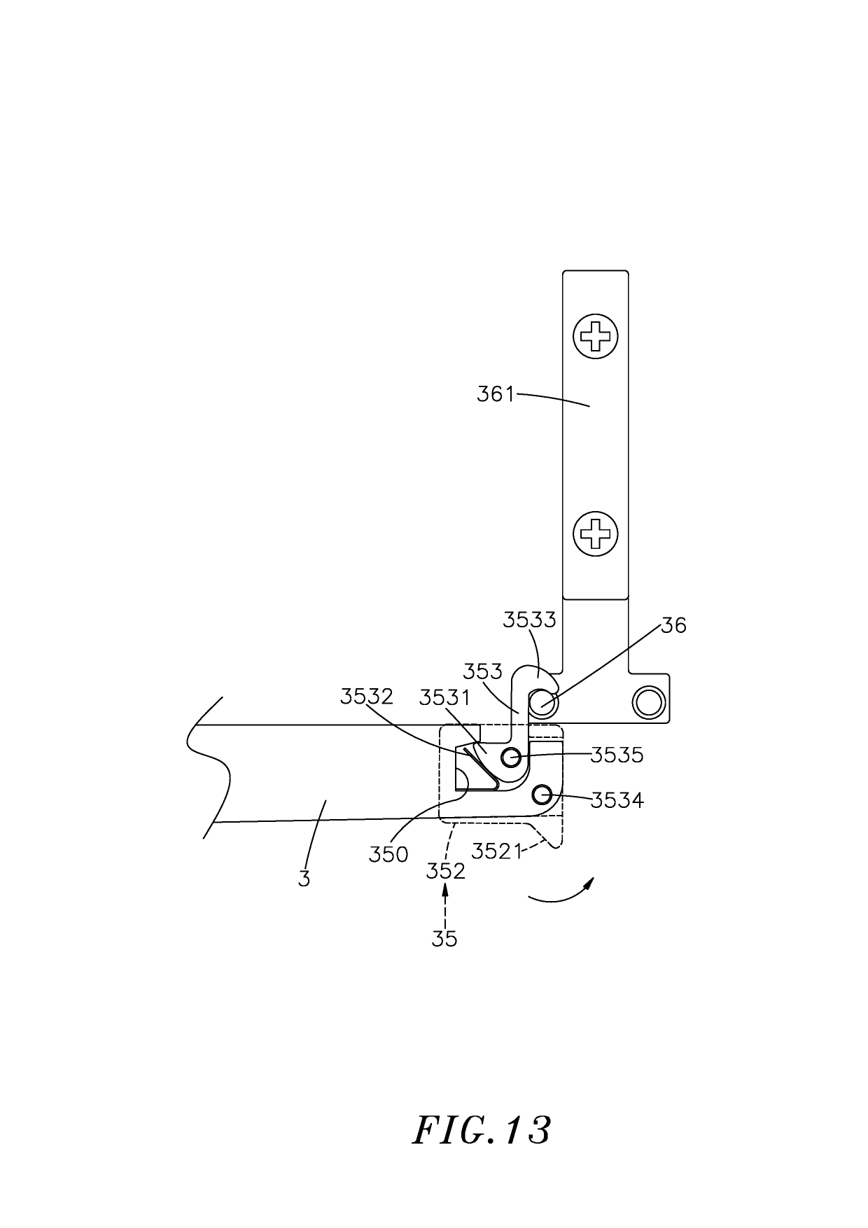

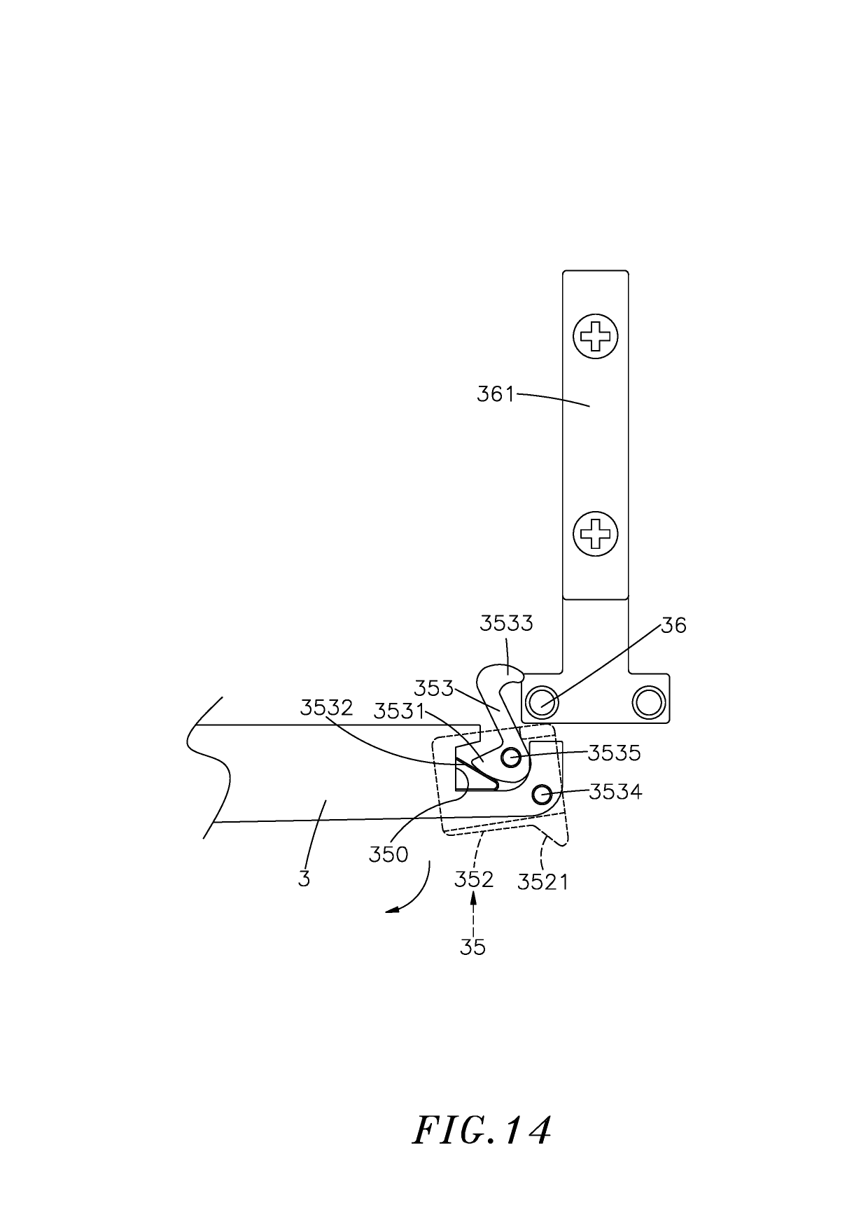

Please refer to FIGS. 1 to 14, the multi-axis rotary handle of the present invention comprises a base 1, a shaft device 2 and a handle 3.

The base 1 comprises a penetrating shaft hole 10 and a guide surface 101 located on the side of the shaft hole 10.

The shaft device 2 comprises a rotating rod 21 and a rotating shaft 22. The rotating rod 21 is inserted into the shaft hole 10 of the base 1. The rotating shaft 22 is provided with a through hole 220, which is used to assemble the rotating rod 21, and a protruding rod 221 is provided on one end of the rotating shaft 22.

The handle 3 is assembled at the shaft device 2, and a coupling groove 31 on one side thereof so as to be movably assembled at the rotating rod 21, and a rotating shaft hole 32 is provided on one side of the coupling groove 31 so as to be assembled at the protruding rod 221 on one side of the rotating shaft 22.

The base 1 of the present invention comprises a first base block 11, a second base block 12, a hollow receiving groove 13 provided between the first base block 11 and the second base block 12, a seat plate 14 extending outward from one side of the first base block 11 and the second base block 12, and a shaft groove 141 provided on the side of the seat plate 14 adjacent to the second base block 12 and extending outward from the shaft hole 10. The shaft hole 10 is provided through the first base block 11 and the second base block 12. The guide surface 101 is provided on one side of the shaft hole 10 of the second base block 12 to extend downward and outward. The rotating rod 21 of the shaft device 2 is installed through the shaft hole 10 of the first base block 11 and the second base block 12, so that the rotating shaft 22 assembled on the rotating rod 21 is located at the receiving groove 13. The seat plate 14 can be assembled at a preset mechanism 4, which can be a hard drive, a multimedia player, a server, an optical drive, a sliding drawer, or a computer motherboard, etc. The rotating shaft 22 of the shaft device 2 is located at the rotating rod 21 and rotates horizontally along the receiving groove 13 in an axial direction, and a spherical arc guide surface 222 is provided on the other side of the rotating shaft 22 opposite to the protruding rod 221.

The handle 3 of the present invention further comprises the U-shaped coupling groove 31 on one side thereof, a stop arm 33 extending outward and provided on one side of the coupling groove 31, an inclined guide surface 331 provided on the side of the stop arm 33 and extending obliquely to the coupling groove 31, a swing arm 34 provided on the longitudinal side of the coupling groove 31 relative to the stop arm 33, and a limit member 341 provided on one side of the rotating shaft hole 32 of the swing arm 34. The rotating shaft hole 32 is provided on the swing arm 34 and can be assembled at the protruding rod 221 on one side of the rotating shaft 22. The limit member 341 can be assembled at the protruding rod 221 (it can be locked, riveted, tightly fitted, interference fit, adhesively bonded or welded, etc.) and pressed against the wall of the rotating shaft hole 32, so that the swing arm 34 and the protruding rod 221 will not separate or fall off. The limit member 341 may be a screw, a rivet or a pin.

In addition, the handle 3 of the present invention is provided with a buckling device 35 on the other side of the coupling groove 31 and the rotating shaft hole 32. The buckling device 35 comprises a receiving space 350 on the side of the handle 3, a fixing hole 351 disposed on the handle 3 on the side of the receiving space 350, a cover 352 assembled at the fixing hole 351 and covering the outside of the receiving space 350, a buckle 353 assembled on the cover 352 and having an actuating side 3531 on one side thereof and a buckle side 3533 provided on an opposite side thereof and protruding out of the receiving space 350 and the cover 352, and an elastic member 3532 located in the receiving space 350 and supported on one side of the actuating side 3531. The elastic member 3532 supported on one side of the actuating side 3531 can be an elastic leaf spring, a spring or a coil spring, etc. Furthermore, a pull portion 3521 is convexly provided on one side of the cover 352.

Moreover, the fixing hole 351 of the buckling device 35 on one side of the handle 3 is used to assemble the cover 352 at the fixing hole 351. The cover 352 can be movably assembled at the fixing hole 351 through a fixing member 3534. The fixing member 3534 can be a rivet, a pin or a shaft. As for the cover 352, the buckle 353 may be assembled by another fixing body 3535, so that the buckle 353 can be moved in the receiving space 350 of the buckling device 35 inside the cover 352. The fixing body 3535 can be a rivet, a pin or a shaft, etc., which can limit the buckle 353 to be movably assembled at the cover 352.

The handle 3 of the present invention further comprises a positioning buckle rod 36 on the outer side relative to the buckling device 35 to allow the buckle side 3533 on one side of the buckle 353 to be movably buckled or unbuckled, and a mounting seat 361 provided on the positioning buckle rod 36 and assembled on the preset mechanism 4. The preset mechanism 4 can be a hard drive, a multimedia player, a server, an optical disc drive, a sliding drawer or a computer motherboard, etc.

Therefore, when the multi-axis rotary handle of the present invention is actually applied and implemented, the base 1, the shaft device 2 and the handle 3 can be used to form a multi-axis rotary handle. At least one rotating handle is installed at the preset mechanism 4, and then the preset mechanism 4 is assembled on a preset rack 5 (which can be a telecommunications chassis, a server chassis, an industrial computer chassis or a central management system chassis, etc.). The preset rack 5 may be provided with a clamping seat 51 on one side thereof, and a clamping groove 510 may be provided on the clamping seat 51. The preset mechanism 4 can be assembled on the track 52 of the preset rack 5, so that the preset mechanism 4 can be moved in and out and pulled out on the track 52. At least one rotary handle is installed at the preset mechanism 4. It is to assemble the handle 3 at the shaft hole 10 in the base 1 by using the rotating rod 21 and the rotating shaft 22 of the shaft device 2. The swing arm 34 on one side of the handle 3 is used to rotate and swing upward in a vertical longitudinal direction with the protruding rod 221 on one side of the rotating shaft 22 as the axis, and then the rotating shaft 22 is used to rotate in a horizontal axial direction with the rotating rod 21 as the axis, so that the coupling groove 31 of the handle 3 is aligned and assembled and covers the rotating rod 21. At the same time, the stop arm 33 on one side of the handle 3 can be used to be locked in the clamping groove 510 of at least one clamping seat 51 of the preset rack 5, so that the preset mechanism 4 can be assembled on the preset rack 5, and the stop arm 33 on one side of the handle 3 can enhance the overall structural strength and facilitate the operation of opening and moving the handle 3.

When the pull portion 3521 of the cover 352 of the buckling device 35 on one side of the handle 3 is pulled open, the actuating side 3531 on one side of the buckle 353 at the fixing body 3535 is driven to swing and squeeze the elastic member 3532, and the buckle side 3533 on the other side of the buckle 353 is driven to swing away from the positioning buckle rod 36 to form a buckle release, and then the force applied to the pull portion 3521 can be released. By grasping and applying force to the handle 3, the coupling groove 31 of the handle 3 rotates and swings in a horizontal axial direction with the rotating rod 21 of the shaft device 2 as the axis, and pulls and rotates away from the outside of the preset mechanism 4. At the same time, the rotating shaft 22 rotates along the receiving groove 13 with one side of the arc guide surface 222, and the stop arm 33 on the side of the handle 3 rotates and exits along the clamping groove 510 of the clamping seat 51, so that the swing arm 34 on one side of the handle 3 rotates in a horizontal axial direction with the protruding rod 221 on one side of the rotating shaft 22 as the axis, and the stop arm 33 slides away along the rotating rod 21 by using the inclined guide surface 331 on one side of the stop arm 33.

When the handle 3 is swung and moved to a position where the seat plate 14 of the base 1 is tilted at an angle of about 40° to 50°, the swing arm 34 of the handle 3 can be used to rotate and swing in a vertical longitudinal direction along the protruding rod 221, and the stop arm 33 is vertically swung and displaced along the guide surface 101 at the second base block 12, so that the handle 3 is rotated in a vertical longitudinal direction toward the protruding rod 221, and is swung to leave the front of the preset mechanism 4, and is swung to the bottom of the front of the preset mechanism 4 with a displacement of 90° or more. Then, the rotating shaft 22 is rotated and swung in a vertical longitudinal direction along the rotating rod 21, so that the coupling groove 31 is moved away from the rotating rod 21. This provides a wider and more usable space at the opening window frame in front of the preset mechanism 4, making it easier to dock, plug, unplug, repair or replace the preset electronic components inside the preset mechanism 4. It can increase the usability of the preset mechanism 4, improve the convenience of operation, etc., and also provide the preset mechanism 4 with good ventilation, so that various electronic devices and electronic components inside the preset mechanism 4 can have good heat dissipation and cooling effects. The handle 3 is provided with the functions of multi-axis rotation and swing displacement, so that the handle 3 can be applied in multi-axis rotation and swing operation.

Furthermore, the rotating rod 21 of the present invention may be provided with a magnetic body (such as a magnet or a permanent magnet, etc.), so that the stop arm 33 of the handle 3 can be more conveniently positioned and embedded in the clamping groove 510 of the clamping seat 51 of the preset rack 5 by the magnetic effect of the rotating rod 21, thereby achieving the effect of labor saving in application. In addition, a magnetic body (such as a magnet or a permanent magnet, etc.) may be disposed at the coupling groove 31 on one side of the handle 3, so that the swing arm 34 of the handle 3 can be more conveniently rotated and swung along the protruding rod 221 on one side of the rotating shaft 22 in a vertical longitudinal direction, and then the swing arm 34 and the rotating shaft 22 can be rotated along the rotating rod 21 in a horizontal axial direction, allowing the coupling groove 31 of handle 3 to be quickly turned over and aligned and coupled with the rotating rod 21 of the shaft device 2. It also allows the handle 3 to be smoothly moved, flipped, and displaced. The magnetic body (such as a magnet or a permanent magnet, etc.) can be set at the rotating rod 21 or the coupling groove 31 by inlaying, external gluing, or integrally forming inside.

The above-mentioned coupling groove 31 of the handle 3 is pulled away and displaced from the outside of the preset mechanism 4 with the rotating rod 21 of the shaft device 2 as the axis, and the rotating shaft 22 rotates along the receiving groove 13 with one side of the arc guide surface 222 at the same time, so that the handle 3 can rotate and swing in multiple directions at the shaft hole 10 of the base 1 and the rotating rod 21 and the rotating shaft 22 of the shaft device 2. It also has a damping structure application, providing a buffering and stabilizing effect when the handle 3 is pushed, rotated, and swung, making it be convenient to control and apply the direction of the handle 3, while also creating a labor-saving effect when operating the handle 3.

If you want to assemble the preset mechanism 4 at the preset rack 5, you can push and slide the preset mechanism 4 along the track 52 on both sides of the preset rack 5 to the preset position, and then pull and swing the handle 3 in front of the preset mechanism 4 upward with the protruding rod 221 as the axis until it is perpendicular to the seat plate 14 of the base 1. The stop arm 33 of the handle 3 is then inserted into the clamping groove 510 of at least one clamping seat 51 of the preset rack 5 by rotating the coupling groove 31 along the rotating rod 21. At the same time, the buckling device 35 on the other side of the handle 3 uses the buckle side 3533 of the buckle 353 to slide and rotate along the positioning buckle rod 36, and the actuating side 3531 on the other side presses against the elastic member 3532. After the buckle side 3533 slides over the positioning buckle rod 36, the elastic member 3532 pressed by the actuating side 3531 pushes the actuating side 3531 with elastic rebound force to drive the buckle side 3533 to be locked at the positioning buckle rod 36, thereby forming a locking positioning effect, so as to achieve the purpose of limiting the assembly of the preset mechanism 4 at the preset rack 5 and preventing it from being easily separated.

The above is merely a preferred embodiment of the present invention and is not intended to limit the patent scope of the present invention. Therefore, all simple modifications and equivalent structural changes made by using the contents of the description and drawings of the present invention should be included in the patent scope of the present invention and should be declared.

In summary, the multi-axis rotary handle of the present invention can achieve its effect and purpose in practical application. Therefore, this invention is truly a research and development creation with excellent practicality. In order to meet the application requirements for invention patents, we have filed an application in accordance with the law. We hope that the review committee will approve this case as soon as possible to protect the inventor's hard work in research and development. If the review committee has any questions, please feel free to write to us for instructions. The inventor will do his best to cooperate and we will be very grateful.

What is claimed is:

1. A multi-axis rotary handle, comprising: a base, a shaft device and a handle, wherein,
said base comprising a penetrating shaft hole;
said shaft device comprising a rotating rod inserted into said shaft hole of said base, and a rotating shaft assembled on said rotating rod, said rotating shaft comprising a protruding rod provided on one end thereof; and
said handle assembled at said shaft device, said handle comprising a coupling groove located on one side thereof and movably assembled at said rotating rod and a rotating shaft hole provided on one side of said coupling groove and assembled at said protruding rod on one end of said rotating shaft.

2. The multi-axis rotary handle as claimed in claim 1, wherein said base comprises a first base block, a second base block, a hollow receiving groove provided between said first base block and said second base block, and a guide surface extending downward and outward and provided on one side of said shaft hole of said second base block; said shaft hole is provided on said first base block and said second base block; said rotating rod of said shaft device is passed through said shaft hole; said rotating shaft assembled on said rotating rod is located at said receiving groove.

3. The multi-axis rotary handle as claimed in claim 2, wherein said base further comprises a seat plate extending outward from one side of said first base block and said second base block for assembly at a preset mechanism, and a shaft groove provided on the side of said seat plate adjacent to said second base block and extending outward from said shaft hole.

4. The multi-axis rotary handle as claimed in claim 1, wherein said handle further comprises a swing arm provided on one side thereof, said swing arm is rotated along said protruding rod on one side of said rotating shaft of said shaft device in a horizontal axial direction, and then rotated along said rotating rod in a vertical longitudinal direction through said rotating shaft, so that said coupling groove retreats from said rotating rod.

5. The multi-axis rotary handle as claimed in claim 2, wherein said rotating shaft of said shaft device is located at said rotating rod and rotates horizontally along said receiving groove in an axial direction, and a spherical arc guide surface is provided on the other side of said rotating shaft relative to said protruding rod.

6. The multi-axis rotary handle as claimed in claim 1, wherein said coupling groove located on one side of said handle is U-shaped; said handle further comprises a stop arm on one side of said coupling groove and extending outward, an inclined guide surface provided on one side of said stop arm and extending obliquely to said coupling groove, said swing arm provided on a longitudinal side of said coupling groove relative to said stop arm; said rotating shaft hole is provided on said swing arm and assembled on said protruding rod on one side of said rotating shaft.

7. The multi-axis rotary handle as claimed in claim 6, wherein said handle further comprises a limit member provided on one side of said rotating shaft hole of said swing arm and assembled at said protruding rod and pressed against a wall of said rotating shaft hole, said limit member being selectively a screw, a rivet or a pin.

8. The multi-axis rotary handle as claimed in claim 1, wherein said handle further comprises a buckling device on an opposite side thereof relative to said coupling groove and said rotating shaft hole, said buckling device comprising a receiving space located on one side of said handle, a fixing hole disposed on said handle on the side of said receiving space, a cover assembled at said fixing hole and covering said receiving space, a buckle assembled on said cover, said buckle comprising an actuating side on one side thereof located in said receiving space and assembled at said cover, an elastic member located in said receiving space and supported on one side of said actuating side, and a buckle side provided on an opposite side of said buckle relative to said actuating side and protruding out of said receiving space and said cover, said elastic member being selectively an elastic leaf spring, a spring or a coil spring.

9. The multi-axis rotary handle as claimed in claim 8, wherein said handle further comprises a positioning buckle rod located at an outer side relative to said buckling device to allow said buckle side on one side of said buckle to be movably buckled or unbuckled, and a mounting seat provided on said positioning buckle rod and assembled on said preset mechanism.

10. The multi-axis rotary handle as claimed in claim 1, wherein said swing arm on one side of said handle is rotated along said rotating shaft in a vertical longitudinal direction, and then rotated along said protruding rod on one end of said rotating shaft in a horizontal axial direction, so that said coupling groove of said handle is aligned and coupled with said rotating rod of said shaft device.
